(19) United States
(12) Patent Application Publication
(10) Pub. No.: US 2006/0199564 A1
(43) Pub. Date: Sep. 7, 2006

(54) Speaker apparatus for handheld electronic device

(76) Inventors: Frank Tyneski, Kitchener (CA); Roman P. Rak, Waterloo (CA)

Correspondence Address: Brij K. Agarwal;Eckert Seamans Cherin & Mellott, LLC, 44th Floor, 600 Grant Street, Pittsburgh, PA, 15219, US

(21) Appl. No.: 11/063,680

(22) Filed: Feb. 23, 2005

(51) Int. Cl. H05K 11/00; H04B 1/06; H04R 1/02

(52) U.S. Cl. 455/344; 381/335

(57) ABSTRACT

An improved speaker apparatus for use in association with a handheld electronic device includes an actuator, an audio transducer, and a connection that is connectable with the handheld electronic device. The speaker apparatus additionally includes a power system that is connectable with a power source. The connection enables the communication of audio signals between the speaker apparatus and the handheld electronic device, and also provides power to operate and/or charge the handheld electronic device. When the speaker apparatus is connected with the handheld electronic device, the audio transducer serves as both a loudspeaker and a microphone for use in, for example, telephone communications using a wireless communication apparatus of the handheld electronic device.

### BACKGROUND OF THE INVENTION

1. Field of the Invention

The invention relates generally to handheld electronic devices and, more particularly, to a speaker assembly for use with a handheld electronic device.

2. Background Information

Numerous types of handheld electronic devices are known. Examples of such handheld electronic devices include, for instance, personal data assistants (PDAs), handheld computers, two-way pagers, cellular telephones, and the like. Many handheld electronic devices also feature a wireless or other communication capability, although other handheld electronic devices are stand-alone devices that are functional without communication with other devices. Such handheld electronic devices are generally intended to be portable, and thus are of a relatively compact configuration. With advances in technology, handheld electronic devices are built to have progressively smaller form factors yet have progressively greater numbers of applications and features resident thereon.

An advantage provided by handheld electronic devices is the mobility afforded the user. One such mobile use of a handheld electronic device is use in a vehicle. Such handheld electronic devices have not, however, been without limitation.

When a person is driving a vehicle, distractions to the driver in conjunction with use of the handheld electronic device are desirably minimized. However, the use of a handheld electronic device in, for example, a telephone application, while driving can cause distractions to the driver due to the driver's need to observe and manipulate certain buttons on the device, as well as the need for the driver to hold the device in particular position against the user's head. In this last regard, such holding requires the attention of the user in maintaining an appropriate position on the head, and additionally requires a hand to hold the device, a hand which potentially could be better used holding a steering wheel than holding a handheld electronic device.

It is noted that the need for a user to be able to listen to output from a handheld electronic device can arise in numerous situations in addition to the situation of a user's participation in a telephone conversation. It thus would be desirable to provide a solution that reduces distraction to a user of a handheld electronic device and/or that facilitates use of a handheld electronic device, particularly when the user is driving or otherwise in a vehicle.

### SUMMARY OF THE INVENTION

An improved speaker apparatus for use in association with a handheld electronic device includes an actuator, an audio transducer, and a connection that is connectable with the handheld electronic device. The speaker apparatus additionally includes a power system that is connectable with a power source. The connection enables the communication of audio signals between the speaker apparatus and the handheld electronic device, and also provides power to operate and/or charge the handheld electronic device. When the speaker apparatus is connected with the handheld electronic device, the audio transducer serves as both a loudspeaker and a microphone for use in, for example, telephone communications using a wireless communication apparatus of the handheld electronic device.

Accordingly, an aspect of the invention is to provide an improved speaker apparatus that has an audio transducer and that enables the communication of audio signals between the audio transducer and a handheld electronic device.

Another aspect of the invention is to provide an improved speaker apparatus having a case, and further having an acuator disposed on the case.

Another aspect of the invention is to provide an improved speaker apparatus that provides a connection that is connectable with a handheld electronic device and that communicates audio signals to and from the handheld electronic device.

Another aspect of the invention is to provide an improved speaker apparatus having a connection that provides power to a handheld electronic device.

Another aspect of the invention is to provide an improved system including a speaker apparatus and a handheld electronic device and permitting audio signals into and from the handheld electronic device to be provided from and to, respectively, and audio transducer of the speaker apparatus.

These and other aspects of the invention are provided by an improved system, the general nature of which can be stated as including a handheld electronic device and a speaker apparatus. The handheld electronic device comprises a wireless communication apparatus, and the speaker apparatus comprises a case, an audio transducer disposed on the case, and a connection. The connection is connected with the handheld electronic device. The speaker apparatus is structured to provide power to the handheld electronic device over the connection. The connection is structured to transfer between the handheld electronic device and the speaker apparatus audio signals to enable audio signals from the handheld electronic device to be output as audible output by the audio transducer and to enable audio signals from the audio transducer to be transmitted by the wireless communication apparatus.

Other aspects of the invention are provided by an improved speaker apparatus that is structured to be connected with a handheld electronic device having a wireless communication apparatus. The general nature of the speaker apparatus can be stated as including a case, an audio transducer disposed on the case, and a connection structured to be connected with the handheld electronic device. The connection comprises a power connection structured to provide power to the handheld electronic device.

Still other aspects of the invention are provided by an improved speaker apparatus that is structured to be connected with a handheld electronic device having a wireless communication apparatus. The general nature of the speaker apparatus can be stated as including a case, an audio transducer disposed on the case, an actuator disposed on the case, and a connection structured to be connected with the handheld electronic device. The speaker apparatus is structured to generate an actuation signal responsive to an actuation of the actuator. The connection is structured to communicate the actuation signal to the handheld electronic device to at least one of i) accept an incoming audio transmission from the wireless communication apparatus and ii) initiate an audio transmission to the wireless communication apparatus.

### BRIEF DESCRIPTION OF THE DRAWINGS

A further understanding of the invention can be gained from the following Description of the Preferred Embodiment when read in conjunction with the accompanying drawings in which:

FIG. 1 is a perspective view of an improved speaker apparatus in accordance with the invention: and

FIG. 2 is a schematic view of an improved system including the speaker apparatus of FIG. 1.

Similar numerals refer to similar parts throughout the specification.

### DESCRIPTION OF THE PREFERRED EMBODIMENT

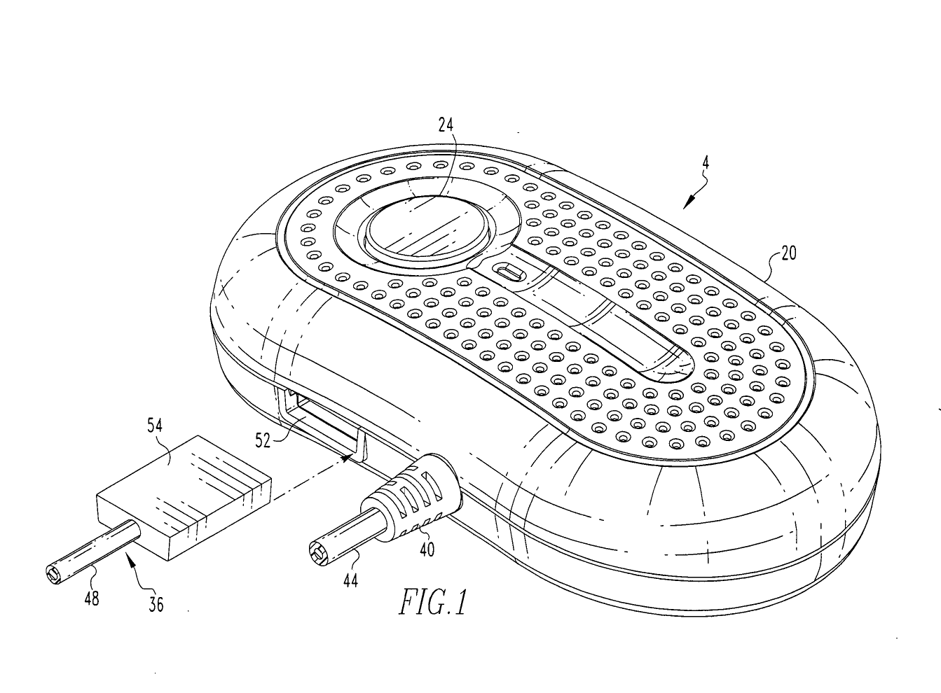

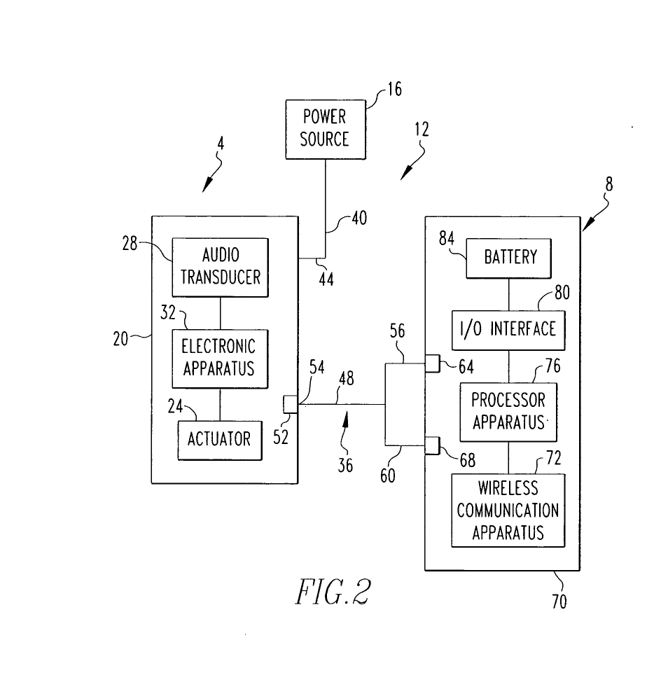

An improved speaker apparatus 4 is indicated generally in FIG. 1. The speaker apparatus 4 is depicted in FIG. 2 as being connected with a handheld electronic device 8 to together form a system 12 that includes the speaker apparatus 4. The system 12, and more particularly the speaker apparatus 4, is connected with a power source 16 that is external to the system 12 and may, for example, include a power source on a vehicle such as a cigarette lighter connected with a battery, a wall power outlet, and the like. As will be described in greater detail below, the speaker apparatus 4 advantageously enables a user to take advantage of certain capabilities of the handheld electronic device 8 in a largely hands-free fashion, that is, with minimal hand effort.

The speaker apparatus 4 can be generally stated as including a case 20 upon which are disposed an actuator 24, an audio transducer 28, and an electronic apparatus 32. The speaker apparatus 4 additionally includes a connection 36 that is connectable with the handheld electronic device 8, and it further includes a power system 40 that is connectable with the power source 16. In the present exemplary embodiment, the power system 40 is characterized by a power cable 44 that extends between the case 20 and the power source 16, although other configurations will be apparent.

It can be seen from FIG. 1 that the exemplary actuator 24 is a large pushbutton disposed on case 20. The exemplary actuator 24 is relatively large and is easily seen and accessed by a user.

In the present exemplary embodiment, the audio transducer 28 is a speaker connected with the electronic apparatus 32. The exemplary audio transducer 28 serves as both a loudspeaker to output audible sounds that can be perceived by the user as well as a microphone that can receive audible signals such as sounds generated by the user, for example, as will be described in greater detail below.

The exemplary connection 36 includes a connection cable 48 that is connectable with a jack 52 disposed on the case 20 of the speaker apparatus 4. The exemplary jack 52 is a Universal Serial Bus (USB) connection, although other types of jacks could be employed without departing from the concept of the invention. As is generally known, a USB connection is capable of providing power and communicating electronic signals out of a single jack 52.

The exemplary connection cable 48 includes a first end 54 that is connectable with the jack 52. The connection 36 can be said to include an audio component and a power component. The audio component is depicted herein in an exemplary fashion as an audio connection 56 at a second end of the connection cable 48. The power component is depicted herein in an exemplary fashion as being a power connection 60 also disposed at the second end of the connection cable 48. The audio connection 56 is connectable with an audio connector 64 of the handheld electronic device 8. The power connection 60 is connectable with a power connector 68 of the handheld electronic device 8. It is understood that in other embodiments (not depicted herein) the connection cable 48 could provide both the audio component and the power component in a single connection with the handheld electronic device 8 without departing from the concept of the invention.

The exemplary handheld electronic device 8 includes a housing 70 upon which are disposed a wireless communication apparatus 72, a processor apparatus 76, an input/output I/O interface 80, and a battery 84. The audio connector 64 and power connector 68 are also disposed on the housing 70.

The wireless communication apparatus 72 provides to the handheld electronic device 8 a wireless communication capability that may include, for example, telephone communication, instant messaging, text messaging, and the like without limitation. The wireless communication apparatus 72 may, for example, provide GSM, GPRS, Bluetooth, Wi-Fi, and/or other types of wireless communication capability without limitation.

The processor apparatus 72 may include, for instance, a processor and a memory. The processor may be, for example and without limitation, a microprocessor (μP) or other type of processor. The memory may be, for example and without limitation, RAM, ROM, EPROM, EEPROM, and/or other types of storage media without limitation. The memory likely will have a number of applications and/or routines resident thereon that are executable on the processor.

The I/O interface 80 can include any of a wide variety of input and/or output devices that are appropriate to the handheld electronic device 8. For example, the I/O interface 80 might include a keypad, a display, a microphone, a loudspeaker, indicator lights, and/or other devices without limitation. The I/O interface 80 may additionally include, for example, the audio connector 64 and/or other types of connectors.

The exemplary battery 84 is a power source that stores and provides the power needed for operating the handheld electronic device 8. The battery can be any of a wide variety of storage devices and may be, for example, a rechargeable battery, although other types of batteries and other storage devices could appropriately be employed.

In accordance with the invention, the speaker apparatus 4 advantageously is connectable with the handheld electronic device 8 in order to enable, for example, audio signals wirelessly received by the wireless communication apparatus 72 to be output by the audio transducer 28 as audible sounds, and/or, for example, to enable audible sounds received by the audio transducer 28 to be wirelessly transmitted as audio signals by the wireless communication apparatus 72. While the speaker apparatus 4 is particularly advantageously employed in conjunction with the handheld electronic device 8 in the context of a telephone application on the handheld electronic device 8, it is understood that the speaker apparatus 4 is advantageously employable in other contexts with respect to the handheld electronic device 8. The speaker apparatus 4 also advantageously provides power to the handheld electronic device 8 in order to charge the battery 84 and/or to power the handheld electronic device 8.

In the present exemplary embodiment, when the connection 36 is connected with audio connector 64 of handheld electronic device 8, the microphone and loudspeaker portions of the I/O interface 80 may become disabled, for example. In their place the audio transducer 28 may function in the role of a microphone and/or a loudspeaker. The audio component of the connection 36, i.e., the audio connection 56, enables the communication of audio signals between the handheld electronic device 8 and the speaker apparatus 4, whereby the speaker apparatus 4 provides a remote microphone and/or loudspeaker device that is connected with handheld electronic device 8.

While the operation of the system 12 is depicted herein in the exemplary embodiment context of a telephone application on the handheld electronic device 8, other uses of the system 12 and the speaker apparatus 4 will be apparent. When an incoming telephone call is received by the wireless communication apparatus 72 of the handheld electronic device 8, for example, the handheld electronic device 8 may generate a ring tone which is communicated over the connection cable 48 and is output as an audible sound by the audio transducer 28. In this regard, the electronic apparatus 32 may include an amplifier to boost the audio signal to the audio transducer 28. Upon the user hearing the ring tone output from the audio transducer 28, the user may actuate the acuator 24 to generate a signal that is provided over the connection cable 48 to the handheld electronic device 8 and which causes the handheld electronic device 8 to accept the incoming telephone call.

During the course of the telephone call, audio and other signals received by the wireless communication apparatus 72 are provided to the speaker apparatus 4 and are output as audible sounds by the audio transducer 28. Sounds from the user are received by the audio transducer 28 and are converted into audio signals that are provided to the handheld electronic device 8 for wireless transmission thereof by the wireless communication apparatus 72. When it is desired to terminate the telephone call, the user can again actuate the actuator 24 to send another signal to the handheld electronic device 8 to terminate the telephone call.

Other uses of the speaker apparatus 4 will be apparent. For example, a telephone call may be initiated on the handheld electronic device 8. If it is desired that the speaker apparatus 4 be employed, the user can actuate the acuator 24, which causes the handheld electronic device 8 to employ the audio transducer 28 of the speaker apparatus 4 as both a microphone and a loudspeaker in place of a microphone and loudspeaker of the I/O interface 80. It is understood that the handheld electronic device 8 might be configured such that merely connecting the audio connection 56 with the audio connection 64 does not automatically cause disabling of the microphone and/or loudspeaker of the I/O interface 80, and rather may provide such disablement only after the actuator 24 of the speaker apparatus 4 has been actuated, for example.

The improved speaker apparatus 4 and system 12 thus enable a user to take advantage of certain aspects of a wireless communication capability, such as an audio communication capability, of the handheld electronic device 8 in a largely hands-free fashion. That is, the user need not hold the speaker apparatus 4, since the speaker apparatus 4 can be disposed on any surface, such as a surface within the interior of a vehicle. Also, the user likewise need not constantly try to keep the handheld electronic device 8 in a specific position relative to the user's ear and mouth. That is, the audio transducer 28 and the electronic apparatus 32 can provide audible sounds at sufficient levels that they are readily heard by the user, and they can also detect audible sounds of sufficiently low volume that sounds such as spoken words and the like from a user can be generated at a meaningful distance from the speaker apparatus 4 and still be detected by the audio transducer 28.

In certain circumstances, a communication such as an incoming telephone call can be accepted with a single actuation of the actuator 24, and can then be terminated with another actuation of the actuator 24. Even though certain functions may require additional manual inputs by a user into the handheld electronic device 8, a telephone conversation and the like may be carried out by the user substantially without needing to hold any structure and without requiring the attention of the user in keeping any device in a certain position with respect to the user's ear and mouth. The largely hands-free, i.e., requiring only minimal hand inputs, operation of the speaker apparatus 4 and the system 12 advantageously relieves burdens on the user and improves safety, such as when the user is operating a vehicle.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the invention which is to be given the full breadth of the claims appended and any and all equivalents thereof.

1. A system comprising:
a handheld electronic device comprising a wireless communication apparatus and an I/D interface; and
a speaker apparatus comprising a case, an audio transducer disposed on the case, an actuator, and a connection, die connection being connected with the handheld electronic device;
the speaker apparatus being structured to provide power to the handheld electronic device over the connection; and
the actuator being actuatable to disable at least a portion of the I/O interface and to enable the connection to transfer between the handheld electronic device and the speaker apparatus audio signals to enable audio signals from the handheld electronic device to be output as audible output by the audio transducer and to enable audio signals from the audio transducer to be transmitted by the wireless communication apparatus.

2. The system of claim 1 wherein the speaker apparatus is structured to generate an actuation sigial responsive to an actuation of the actuator, the connection being structured to communicate the actuation signal to the handheld electronic device, and responsive to said actuation signal, the handheld electronic device being structured to at least one of:
accept an incoming audio transmission from the wireless communication apparatus; and
initiate an audio transfusion to the wireless communication apparatus.

3. The system of claim 1 wherein the speaker apparatus further comprises a power system structured to provide said power to the handheld electronic device, the power system comprising a power cable structured to be connected with a power source.

4. The system of claim 1 wherein the connection comprises a Universal Serial Bus connection connected with the handheld electronic device and being structured to provide said power to the handheld electronic device.

5. The system of claim 4 wherein the handheld electronic device further comprises an audio connector, and wherein the connection includes an audio connection connected with the audio connector of the handheld electronic device to transfer said audio signals between the handheld electronic device and the speaker apparatus.

6. A speaker apparatus structured to be connected with a handheld electronic device having a wireless communication apparatus and an I/O interface, the speaker apparatus comprising:
a case;
an actuator,
an audio transducer disposed on the case; and
a connection structured to be connected with the handheld electronic device, the connection comprising a power connection and an audio connections the power connection being structured to provide power to the handheld electronic device, the audio connection being structured to be connected with the handheld electronic device to transfer audio signals between the handheld electronic device and the speaker apparatus, the actuator being structured to be actuatable to disable at least a portion of the I/O interface and to enable audio signals received from the handheld electronic device to be output as audible output by the audio transducer and to enable audio signals from the audio transducer to be provided to the handheld electronic device for wireless transmission.

7. The speaker apparatus of claim 6 wherein the speaker apparatus is structured to generate an actuation signal responsive to an actuation of the actuator, the connection being structured to communicate the actuation signal to the handheld electronic device to at least one of accept an incoming audio transmission from the wireless communication apparatus and initiate an audio transmission to the wireless communication apparatus.

8. The speaker apparatus of claim 6 wherein the connection further comprises a power system structured to provide said power to the handheld electronic device, the power system comprising a power cable structured to be connected with a power source.

9. The speaker apparatus of claim 6 wherein the power connection comprises a Universal Serial Bus connection structured to be connected with the handheld electronic device and to provide said power to the handheld electronic device.

10. (canceled)

11. A speaker apparatus structured to be connected with a handheld electronic device having a wireless communication apparatus and an I/O interface, the speaker apparatus comprising:
a case;
an audio transducer disposed on the case;
an actuator disposed on the case and structured to be actuatable to disable at least a portion of the I/O interface; and
a connection structured to be connected with the handhold electronic device, the speaker apparatus being structured to generate an actuation signal responsive to an actuation of the actuator, the connection being structured to communicate the actuation signal to the handheld electronic device to at least one of accept an incoming audio transmission from the wireless communication apparatus and initiate an audio transmission to the wireless communication apparatus.

12. The speaker apparatus of claim 11 wherein the connection further comprises a power connection, the power connection being structured to provide power to the handheld electronic device.

13. The speaker apparatus of claim 12 wherein the connection further comprises a power system structured to provide said power to the handheld electronic device, the power system comprising a power cable structured to be connected with a power source.

14. The speaker apparatus of claim 13 wherein the connection further comprises an audio connection structured to be connected with the handheld electronic device to transfer audio signals between the handheld electronic device and the speaker apparatus, the audio connection being structured to enable audio signals received from the handheld electronic device to be output as audible output by the audio transducer and to enable audio signals from the audio transducer to be provided to the handheld electronic device for wireless transmission.

15. The speaker apparatus of claim 12 wherein the power connection comprises a Universal Serial Bus connection structured to be connected with the handheld electronic device and to provide said power to the handheld electronic device.
